(19) United States
(12) Patent Application Publication
(10) Pub. No.: US 2026/0221723 A1
(43) Pub. Date: Jul. 30, 2026

(54) SEMICONDUCTOR LASER AND METHOD FOR PRODUCING A SEMICONDUCTOR LASER

(71) Applicant: ams-OSRAM International GmbH, Regensburg (DE)

(72) Inventors: Hubert HALBRITTER, Dietfurt (DE); Adrian Stefan AVRAMESCU, Regensburg (DE); Norwin VON MALM, Nittendorf (DE)

(21) Appl. No.: 19/143,984

(22) PCT Filed: Nov. 29, 2023
(86) PCT No.: PCT/EP2023/083525

§ 371 Date: Jun. 27, 2025

(30) Foreign Application Priority Data
Dec. 29, 2022 (DE) 10 2022 134 979.9

(51) Int. Cl. H01S 5/11

(52) U.S. Cl. CPC H01S 5/11

(57) ABSTRACT

A semiconductor laser includes a semiconductor layer sequence with a p-doped layer, an n-doped layer and an active region arranged between the p-doped layer and the n-doped layer for generating electromagnetic radiation. The semiconductor laser also includes an optical structure. The optical structure is arranged on the side of the active region facing away from the p-doped layer. The optical structure includes a refractive index varying in a lateral direction for the electromagnetic radiation generated by the active region. The n-doped layer is arranged at least partially between the active region and the optical structure. The optical structure is arranged on the side of the n-doped layer facing away from the active region.

A semiconductor laser and a method for producing a semiconductor laser are disclosed.

A task to be solved is to specify a semiconductor laser that can be operated efficiently. In addition, a task to be solved is to specify a method by which such a semiconductor laser can be produced efficiently.

According to at least one embodiment of the semiconductor laser, the semiconductor laser is a surface-emitting semiconductor laser. The surface-emitting semiconductor laser may, for example, be a VCSEL (vertical-cavity surface-emitting laser) or a PCSEL (photonic crystal surface-emitting laser). Preferably, the semiconductor laser is a thin film semiconductor laser. In other words, a growth substrate is partially or completely removed from the semiconductor laser. PCSELs, for example, have a large aperture.

According to at least one embodiment of the semiconductor laser, the semiconductor laser comprises a semiconductor layer sequence with a p-doped layer, an n-doped layer and an active region arranged between the p-doped layer and the n-doped layer for generating electromagnetic radiation. The electromagnetic radiation is, for example, radiation, in particular laser radiation in the visible range, in the UV range and/or in the IR range of the electromagnetic spectrum. The semiconductor layer sequence comprises, for example, a III-V semiconductor compound material. For example, the semiconductor layer sequence can include, comprise and/or consist of GaN and/or InGaN. The active region can, for example, comprise a pn junction and/or a quantum well structure.

The layers of the semiconductor layer sequence can each comprise a layer thickness. The layer thickness is preferably an extension, for example an average extension, of the layer along a stacking direction of the layers of the semiconductor layer sequence. The layers of the semiconductor layer sequence are arranged consecutively along a stacking direction, for example. The layer thickness of the p-doped layer is, for example, including 50 nm to including 500 nm, for example including 150 nm to including 400 nm or for example including 200 nm to including 300 nm. The n-doped layer can comprise a layer thickness of including 30 nm to including 250 nm, in particular including 50 nm to including 200 nm.

The layers of the semiconductor layer sequence can comprise a main extension plane. The main extension plane of a layer of the semiconductor layer sequence is preferably a plane which is perpendicular to the stacking direction of the semiconductor layer sequence.

According to at least one embodiment, the semiconductor laser comprises an optical structure. The optical structure is, for example, configured to influence at least one degree of freedom of the electromagnetic radiation emitted by the active region. For example, at least one degree of freedom of the electromagnetic radiation can be specifically influenced. In other words, the electromagnetic radiation emitted by the semiconductor laser can be at least partially adjusted and/or adapted, in particular specifically adjusted and/or adapted, by means of the optical structure.

The at least one degree of freedom of the electromagnetic radiation is, for example, an emission wavelength and/or an emission direction of the semiconductor laser. For example, the optical structure can form a wavelength filter.

In particular, the optical structure can be arranged in the vicinity of the active region. This can be particularly advantageous for a semiconductor laser that is formed by or includes a PCSEL. For example, the optical structure is arranged in close proximity to the active region. Close can thereby mean that a distance between the optical structure and the active region is less than or equal to 2 times the layer thickness of the n-doped layer. For example, the distance is at most 1.5 times, one time, half or one quarter of the layer thickness of the n-doped layer. In particular, the distance is a distance between the active region and the point of the optical structure arranged closest to the active region.

For example, the optical structure is a periodically varying structure. Thus, for example, the optical structure comprises a periodically varying refractive index.

The optical structure can be one-dimensional, two-dimensional or three-dimensional. This means that the refractive index can vary in one lateral direction or two orthogonal lateral directions or two orthogonal lateral directions and one direction perpendicular to the main extension plane of the active region, for example vary periodically.

The optical structure can comprise a fill factor. For example, the optical structure is formed by structuring a layer. For example, cut-outs, in particular at least one cut-out, are generated in the layer, for example in the n-doped layer. For example, a material that comprises a higher or a lower refractive index than the layer, for example, can be arranged in the cut-outs. For example, the cut-outs of the layer, for instance of the n-doped layer, are completely filled with the material. The cut-outs are filled with SiO₂, air and/or ITO, for example. The cut-outs can also be referred to as holes in the photonic crystal (PC holes) or as a cell, for example. The fill factor of the optical structure can then be, in particular, the proportion of the cut-outs in the n-doped layer. For example, the fill factor is the area fraction of the cut-outs in the area of the n-doped layer along the main extension plane of the n-doped layer. The cut-outs comprise, for example, an expansion in a direction parallel to the main extension plane of the semiconductor layer sequence. For example, a diameter or a lateral extension along a direction parallel to the main extension plane of a cut-out or all cut-outs of the optical structure corresponds in each case at most to the wavelength of the electromagnetic radiation generated by the active region. In particular, a diameter of a cut-out is at most or at least approximately half the wavelength of the electromagnetic radiation generated by the active region.

The cut-outs comprise a depth, for example. The depth of the cut-outs is in particular an extension of the cut-out in a direction perpendicular to the main extension plane of the semiconductor layer sequence. Preferably, the depth of a cut-out corresponds to the maximum depth of the corresponding cut-out.

It is possible that the cut-outs or PC holes do not extend completely through the n-doped layer.

The optical structure can comprise a thickness. The thickness of the optical structure is, for example, an expansion of the optical structure along a direction that runs perpendicular to a main extension plane of the semiconductor layer sequence or the n-doped layer. For example, in the case of a one-dimensional or two-dimensional optical structure, the thickness of the optical structure results from the extension of the cut-outs along a direction perpendicular to the main extension plane of the n-doped layer, or from the depth of the cut-outs.

According to at least one embodiment of the semiconductor laser, the optical structure is arranged on the side of the active region facing away from the p-doped layer. For example, the n-doped layer comprises the optical structure. Alternatively or additionally, the optical structure can partially comprise the n-doped layer. The optical structure can then be partially, in particular only partially, formed by the n-doped layer. Alternatively or additionally, the optical structure can be arranged on the side of the n-doped layer facing away from the active region. For example, the optical structure is flush or almost flush with the n-doped layer in a direction perpendicular to a main extension plane of the active region. Alternatively or additionally, the n-doped layer can be arranged on the side of the optical structure facing away from the active region.

The optical structure can be arranged in the n-doped layer and/or be adjacent, in particular directly adjacent, to the side of the n-doped layer facing away from the active region.

It is possible that the n-doped layer is at least partially arranged between the active region and the optical structure. This can mean that the n-doped layer is completely arranged between the active region and the optical structure.

The n-doped layer can be multilayered. The optical structure can then be arranged on the side of the multilayered n-doped layer facing away from the active region. In particular, this can mean that the optical structure is not arranged between two n-doped layers that are spaced apart from each other. For example, no n-doped layer, for example no further n-doped layer, follows the optical structure on its side facing away from the active region.

According to at least one embodiment of the semiconductor laser, the optical structure comprises a refractive index that varies in a lateral direction for the electromagnetic radiation generated by the active region. The lateral direction is in particular a direction which runs parallel to a main extension plane of the semiconductor layer sequence, for example parallel to the main extension plane of the active region.

The variation of the refractive index of the optical structure for the electromagnetic radiation generated by the active region is, in particular, not random. In other words, the refractive index of the optical structure varying in a lateral direction can be deliberately formed.

For example, the optical structure comprises at least two regions with different refractive indices. In particular, the optical structure can comprise more than two regions, for example a plurality of regions with different refractive indices from each other. The refractive indices of the at least two regions may be different in pairs. For example, the at least two regions with different refractive indices in pairs are arranged alternately, in particular alternately along the lateral direction. Alternatively or additionally, the optical structure can comprise regions with different refractive indices along a direction that is perpendicular to the lateral direction.

A region of the optical structure is thereby preferably formed by the layer which is structured to generate the optical structure.

According to at least one embodiment of the semiconductor laser, the semiconductor laser comprises a semiconductor layer sequence with a p-doped layer, an n-doped layer and an active region arranged between the p-doped layer and the n-doped layer for generating electromagnetic radiation, and an optical structure, wherein the optical structure is arranged on the side of the active region facing away from the p-doped layer, and the optical structure comprises a refractive index varying in a lateral direction for the electromagnetic radiation generated by the active region.

An idea of the semiconductor laser described here is, among other things, to specify a semiconductor laser in which the optical structure is arranged on the n-doped side. In particular, the semiconductor laser described here can thus have particularly few defects, since the optical structure is structured, for example, only after the semiconductor layer sequence has been grown. In a thin film semiconductor laser, the growth substrate is partially or completely removed. Hence, the n-doped layer is accessible. Thus, the optical structure can be efficiently structured close to the active region subsequently.

Due to the subsequent structuring of the optical structure, the optical structure does not influence the formation of the active region, as the active region was formed prior to the formation of the optical structure. In other words, overgrowth of the optical structure is advantageously not necessary with the semiconductor laser described here. The active region can thus comprise particularly few defects and damage or be free or almost free of defects.

According to at least one embodiment, the optical structure comprises a photonic crystal. In particular, the optical structure can comprise and/or consist of a photonic crystal. The optical structure is, for example, a one-dimensional (1D), two-dimensional (2D) or three-dimensional (3D) photonic crystal.

According to at least one embodiment of the semiconductor laser, a high refractive index layer is arranged at the side of the n-doped layer facing away from the active region, wherein a refractive index of the high refractive index layer is at least 1.7. For instance, the refractive index of the high refractive index layer is greater than or equal to 1.8, greater than or equal to 1.9 or greater than or equal to 2. For example, the refractive index of the high refractive index layer is greater than an average refractive index of the semiconductor layer sequence. In particular, the refractive index of the high refractive index layer is greater than a refractive index of the n-doped layer. The high refractive index layer can comprise a layer thickness of at least 100 nm, for example at least 200 nm, in particular at least 300 nm.

Due to the high refractive index layer, the mode is pushed towards the n-doped layer. An overlap of the mode with the optical structure can thus be increased.

According to at least one embodiment, the high refractive index layer is transmissive for the electromagnetic radiation generated by the active region. Alternatively or additionally, the high refractive index layer can be transmissive to the electromagnetic radiation influenced by the optical structure. That the high refractive index layer is transmissive to electromagnetic radiation can thereby mean that the high refractive index layer is at least translucent, in particular transparent to the electromagnetic radiation.

The high refractive index layer can comprise a transmission coefficient. Preferably, the transmission coefficient is greater than zero. In other words, the electromagnetic radiation can be at least partially transmitted through the high refractive index layer. The electromagnetic radiation can thus be efficiently coupled out of the semiconductor laser.

According to at least one embodiment of the semiconductor laser, an electrically conductive layer is arranged between the high refractive index layer and the n-doped layer, wherein the electrically conductive layer is configured to electrically contact the n-doped layer.

For instance, the electrically conductive layer comprises a transparent conductive oxide (TCO), for example indium tin oxide, or ITO for short.

For instance, the electrically conductive layer is directly adjacent to the high refractive index layer and/or the n-doped layer. In other words, the electrically conductive layer can be arranged directly between the high refractive index layer and the n-doped layer. Preferably, the electrically conductive layer is adjacent over the entire surface of the n-doped layer and/or the optical structure. The electrically conductive layer can be configured for current spreading and for current injection in the semiconductor layer sequence. For example, the electrically conductive layer is configured for electrical contacting of the semiconductor layer sequence, in particular of the n-doped layer and/or the optical structure. A layer thickness of the electrically conductive layer is, for example, at most 100 nm, in particular at most 50 nm.

According to at least one embodiment of the semiconductor laser, a further electrically conductive layer is arranged on the side of the high refractive index layer facing away from the active region, and the high refractive index layer comprises at least one via.

The at least one via preferably extends from the further electrically conductive layer to the electrically conductive layer or vice versa. The at least one via extends, for example, through the high refractive index layer. In particular, the at least one via can extend completely through the high refractive index layer. By means of the at least one via, the electrically conductive layer can be electrically conductively connected to the further electrically conductive layer. For example, the further electrically conductive layer is configured as a contact layer. The electrically conductive layer is then configured as a current distribution layer or current spreading layer, for example.

The at least one via can be formed channel-shaped or line-shaped. Channel-shaped can mean here that a lateral expansion of the via in mutually perpendicular directions is the same or at least approximately the same. Line-shaped can thereby mean that the lateral expansion of the via along one direction of the mutually perpendicular directions is greater, for example a multiple, of the lateral expansion of the via along the direction perpendicular to this direction.

If the via is only required as an electrically conductive connection from the electrically conductive layer to the further electrically conductive layer, the via can be arranged and generated in the high refractive index layer in a simplified manner. The via then does not have to be positioned precisely, for example exactly at the cut-outs of the optical structure. Preferably, the via is positioned in such a way that an absorption of the electromagnetic radiation generated by the active region at the via is minimized.

For example, the via comprises an expansion in a direction parallel to the main extension plane of the semiconductor layer sequence. The expansion of the via can be the diameter of the via. The expansion of the via is, for example, at least approximately at most half the wavelength of the electromagnetic radiation generated by the active region. For example, a diameter of the via corresponds at least approximately to the diameter of a cut-out in the optical structure. Alternatively, in particular if the vias are only configured for electrical contacting of the semiconductor layer sequence, the diameter or the lateral expansion of the via can be greater than the wavelength of the electromagnetic radiation generated by the active region.

According to at least one embodiment of the semiconductor laser, the semiconductor laser comprises at least one further via. The at least one further via can be arranged spaced apart from the at least one via. For example, the at least one further via runs parallel to the at least one via. Alternatively, the at least one further via can run perpendicular to the at least one via. For example, the at least one further via and the at least one via are in places in direct contact. For example, the vias are formed grid-shaped. The at least one further via can comprise the same or at least partially the same properties as the at least one via.

Due to at least two vias in the high refractive index layer, a current distribution in the electrically conductive layer can be improved.

According to at least one embodiment of the semiconductor laser, the semiconductor laser comprises at least one further via, and the at least one via and the at least one further via are configured to at least partially extend the optical structure. The at least one via preferably comprises a lower refractive index than the high refractive index layer. For example, the at least one via overlaps with a PC hole in a lateral direction. In particular, the at least one via can completely overlap with a PC hole. A lateral expansion of the at least one via can thereby, for example, correspond at least approximately to a lateral expansion of the PC hole. The optical structure then comprises, for example, at least partially the at least one via and/or the high refractive index layer. For example, the optical structure is formed as a double lattice structure by means of the at least one via.

According to at least one embodiment of the semiconductor laser, the high refractive index layer comprises niobium oxide (NbO), titanium oxide (TiO) and/or gallium nitride (GaN). A refractive index of the high refractive index layer or an average refractive index of the high refractive index layer is preferably greater than an average refractive index of the semiconductor layer sequence.

According to at least one embodiment of the semiconductor laser, the high refractive index layer comprises a thickness of at least 150 nm. For example, the layer thickness of the high refractive index layer is at least 200 nm. Due to a high refractive index layer, which is formed at least 150 nm thick, the mode profile can be efficiently pushed or shifted to the n-doped side. This improves an overlap of the mode profile of the electromagnetic radiation with the optical structure.

According to at least one embodiment of the semiconductor laser, a low refractive index layer is arranged on the side of the p-doped layer facing away from the active region, wherein a refractive index of the low refractive index layer is smaller than an average refractive index of the semiconductor layer sequence.

The low refractive index layer comprises, for example, an ITO layer and/or a Bragg mirror. The low refractive index layer can comprise a low refractive index layer stack and/or alternatively or additionally to the ITO layer and/or the Bragg mirror comprise further layers and/or layer stacks.

For example, the low refractive index layer comprises a refractive index, for example an average refractive index, which is smaller than a refractive index, for example an average refractive index, of the semiconductor layer sequence. Alternatively, the refractive index of the low refractive index layer can be equal to an average refractive index of the semiconductor layer sequence.

By arranging a low refractive index layer on the side of the semiconductor layer sequence on which the p-doped layer is arranged, a mode profile of the electromagnetic radiation can be pushed or shifted further towards the n-doped side. This improves an overlap of the mode profile of the electromagnetic radiation with the optical structure. Improved can thereby mean in particular that the overlap is increased and/or maximized.

According to at least one embodiment of the semiconductor laser, a metal reflector is arranged on the side of the p-doped layer facing away from the active layer. For example, the metal reflector is arranged on the side of the low-refractive index layer facing away from the p-doped layer. Alternatively, the metal reflector can be directly adjacent to the p-doped layer.

According to at least one embodiment of the semiconductor laser, the sum of the layer thicknesses of the p-doped layer, the low refractive index layer and/or the metal reflector is at least 100 nm. For example, the sum of the layer thicknesses corresponds to at least the wavelength of the electromagnetic radiation emitted by the active region, in particular the sum of the layer thicknesses corresponds to a multiple of the wavelength. For example, the sum of the layer thicknesses is less than three times the wavelength of the electromagnetic radiation emitted by the active region. This can improve a resonance in the semiconductor laser.

According to at least one embodiment of the semiconductor laser, the semiconductor laser comprises a contacting, the contacting comprises an opening, and at least one conductive connection is arranged in the opening.

The contacting is, for example, configured for electrical contacting of the semiconductor layer sequence, in particular of the p-doped layer or the n-doped layer. The contacting comprises, for example, an electrically conductive material, for instance a metal.

The opening of the contacting is, for example, circular, rectangular, free-form, almost circular or almost rectangular. In particular, the opening of the contacting is arranged in such a way that the optical structure is not or largely not covered by the contacting. In other words, the opening of the contacting is arranged, for example, at the optical structure and/or the n-doped layer or the p-doped layer. The optical structure and/or n-doped layer or p-doped layer arranged thereon is freely accessible through the opening. The optical structure and/or the n-doped layer or the p-doped layer is therefore free of the material of the contacting, particularly in the area of the opening.

The contacting can comprise at least one conductive connection. The at least one conductive connection of the contacting can be arranged in the opening of the contacting. For example, at least two conductive connections or a plurality of conductive connections are arranged in the opening of the contacting. The at least one conductive connection of the contacting extends, for example, from the contacting into the opening of the contacting. For example, the at least one conductive connection extends completely across the opening. The, for example, at least two conductive connections can, for example, run parallel to each other. The at least one conductive connection can be formed as a metal line and/or wire. The at least one conductive connection is, for example, configured for current impression in the semiconductor layer sequence.

Due to the at least one conductive connection in the opening of the contacting, current distribution in the layer adjacent to the contacting is improved. Electromagnetic radiation generated and emitted by the semiconductor laser can be coupled out of the semiconductor laser particularly efficiently in the area of the opening.

According to at least one embodiment of the semiconductor laser, the active region emits polarized electromagnetic radiation during operation and the at least one conductive connection of the contacting extends perpendicular to the polarization of the polarized electromagnetic radiation emitted by the active region. In particular, the at least one conductive connection extends perpendicular to the transverse electric field (TE field). The at least one conductive connection of the contacting is then transparent or approximately transparent to the electromagnetic radiation emitted by the semiconductor laser. In this way, the electromagnetic radiation can be efficiently coupled out of the semiconductor laser.

According to at least one embodiment of the semiconductor laser, the n-doped layer comprises a layer thickness of at least 300 nm. The n-doped layer comprises a particularly high layer thickness, for example. The layer thickness of the n-doped layer can be at least 350 nm, for example, for example at least 400 nm. The n-doped layer can be highly doped. For example, the n-doping of the n-doped layer is greater than or equal to 2*10¹⁸ 1/cm³.

An advantage of this embodiment is that due to the particularly large layer thickness of the n-doped layer an overlap of the mode of the electromagnetic radiation generated by the active region with the optical structure or the photonic crystal, is increased.

According to at least one embodiment, the fill factor of the optical structure is at most 30%, for example at most 20%, in particular at most 15% or for example at most 10%. As a result, for example, a contact area in which the electrically conductive layer is in direct contact with the n-doped layer is increased and a current impression in the n-doped layer is improved.

According to at least one embodiment, the semiconductor laser comprises a cover and/or an anti-reflection coating.

The cover is arranged at the optical structure, for example. In particular, the cover can be arranged at the side of the contacting facing away from the optical structure. The cover can partially or completely cover the opening of the contacting. The cover is, for example, transmissive, in particular transparent, for the electromagnetic radiation generated and/or emitted by the active region and/or by the optical structure. For example, the cover comprises glass or is made of glass. The cover can be connected to the contacting by soldering, gluing and/or metal-to-metal bonding.

For example, the cover comprises an anti-reflective coating (AR coating). In particular, the cover comprises an AR coating on the side facing towards the semiconductor layer sequence and/or on the side facing away from the semiconductor layer sequence. In particular, the AR coating can completely cover the corresponding side. Alternatively or additionally, the n-doped layer can comprise an AR coating. For example, the AR coating is applied to the n-doped layer. In particular, the AR coating can be arranged directly on the side of the n-doped layer facing away from the active region.

According to at least one embodiment, a carrier is arranged on the side of the p-doped layer facing away from the active region. The carrier is, for example, the mechanically supporting component of the semiconductor laser.

Furthermore, a method for producing a semiconductor laser is provided. The semiconductor laser described herein is preferably producible by a method for producing a semiconductor laser described herein. In other words, all features disclosed for the method for producing a semiconductor laser are also disclosed for the semiconductor laser and vice versa.

According to at least one embodiment of the method for producing a semiconductor laser, the method comprises growing a semiconductor layer sequence on a growth substrate. For example, an n-doped layer of the semiconductor layer sequence is grown on the growth substrate before a p-doped layer of the semiconductor layer sequence.

The growth substrate comprises, for example, GaN, Si and/or sapphire. Additionally, the growth substrate can include further layers, which, for example, comprise InAlGaN. In this way, a low defect density can be achieved. This means that the semiconductor layers of the semiconductor layer sequence can be grown on the growth substrate with as few defects as possible. For example, the growth substrate comprises a release layer. After the semiconductor layer sequence has been grown onto the growth substrate, the growth substrate can be removed. For example, the growth substrate is removed by means of the release layer. The growth substrate is removed from the semiconductor layer sequence using laser lift-off, for example.

By removing the growth substrate, the n-doped layer is then easily accessible. The optical structure can thus be generated subsequently and in a simplified manner in the n-doped layer.

According to at least one embodiment of the method for producing a semiconductor laser, the method comprises providing a layer sequence comprising a semiconductor layer sequence with a p-doped layer, an n-doped layer and an active region arranged between the p-doped layer and the n-doped layer for generating electromagnetic radiation on a carrier. The carrier is thereby preferably arranged on the side of the p-doped layer facing away from the active region.

According to at least one embodiment of the method for producing a semiconductor laser, the method comprises providing a further carrier with a further layer sequence arranged on the further carrier. The further layer sequence comprises at least one layer. The at least one layer of the further layer sequence comprises, for example, a transparent conductive oxide, for example ITO, a highly refractive dielectric, gallium nitride, in particular n-doped gallium nitride and/or a material with no or low absorption, for example silicon dioxide (SiO₂). The further carrier comprises, for example, sapphire or is formed from sapphire.

According to at least one embodiment of the method for producing a semiconductor laser, the method comprises forming an optical structure, wherein the optical structure comprises a refractive index varying in the lateral direction for the electromagnetic radiation generated by the active region. For example, the optical structure is a photonic crystal or the optical structure comprises a photonic crystal. Generating the optical structure comprises, for example, structuring a layer, for instance the n-doped layer and/or an electrically conductive layer. Structuring the layer involves, for example, partially removing the layer. Areas in which the layer is removed can comprise a refractive index that is different from the refractive index of the layer.

According to at least one embodiment of the method for producing a semiconductor laser, the method comprises bonding the layer sequence to the further layer sequence. Preferably, the layer sequence is connected on the side facing away from the carrier to the side of the further layer sequence facing away from the further carrier. In the case of air and/or gas-filled PC holes in particular, the layer sequences are bonded together in a vacuum and/or in a defined atmosphere, for example. The defined atmosphere can thereby comprise a specific gas, for example.

According to at least one embodiment of the method for producing a semiconductor laser, the method comprises the following steps:
providing a layer sequence comprising a semiconductor layer sequence with a p-doped layer, an n-doped layer and an active region arranged between the p-doped layer and the n-doped layer for generating electromagnetic radiation on a carrier,
providing a further carrier with a further layer sequence arranged on the further carrier,
forming an optical structure, wherein the optical structure comprises a refractive index varying in the lateral direction for the electromagnetic radiation generated by the active region, and
bonding the layer sequence to the further layer sequence.

For example, the steps listed are carried out in the order given.

According to at least one embodiment of the method for producing a semiconductor laser, the optical structure is formed in the layer sequence and/or in the further layer sequence prior to bonding the layer sequence to the further layer sequence. The further layer sequence may comprise the electrically conductive layer. ITO can be processed in a simplified manner using plasma etching. The optical structure can thus be produced in a simplified and reproducible manner. If the optical structure is formed in the ITO layer, an absorption in the ITO is reduced due to the fact that the ITO is partially removed.

According to at least one embodiment of the method for producing a semiconductor laser, the optical structure is formed in the layer sequence, and after bonding the layer sequence to the further layer sequence, the optical structure is at least partially confined by the further layer sequence. This can mean that the further layer sequence is at least partially directly adjacent to the optical structure, in particular directly adjacent to at least one PC hole of the optical structure.

According to at least one embodiment of the method for producing a semiconductor laser, at least one via is formed in the further layer sequence after bonding the layer sequence to the further layer sequence.

According to at least one embodiment of the method for producing a semiconductor laser, the further carrier is removed after bonding the layer sequence to the further layer sequence. The further carrier is removed, for example, by means of laser lift-off.

In the following, the semiconductor laser described herein and the method for producing a semiconductor laser described herein are explained in more detail in connection with exemplary embodiments and the associated figures.

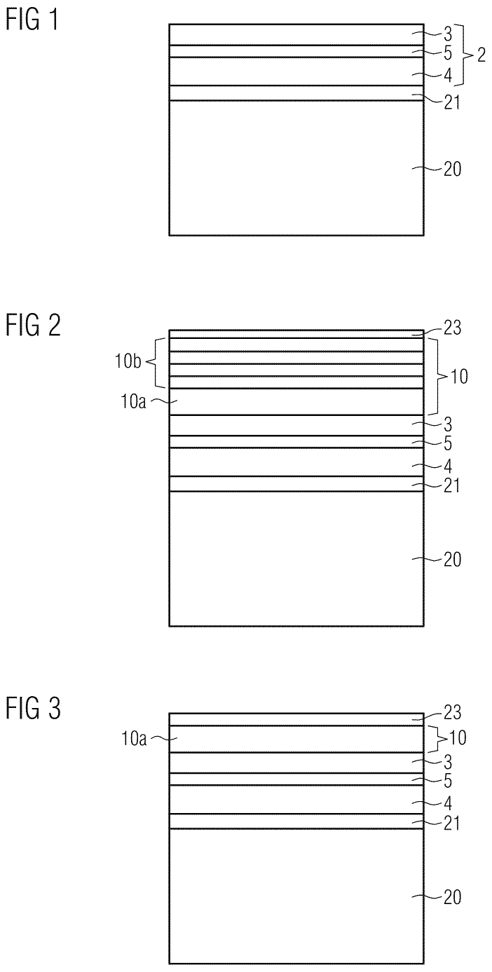

FIG. 1 shows a semiconductor layer sequence on a growth substrate.

FIGS. 2 to 5 show the semiconductor layer sequence shown in FIG. 1 with additional layers arranged at the p-doped layer according to various exemplary embodiments.

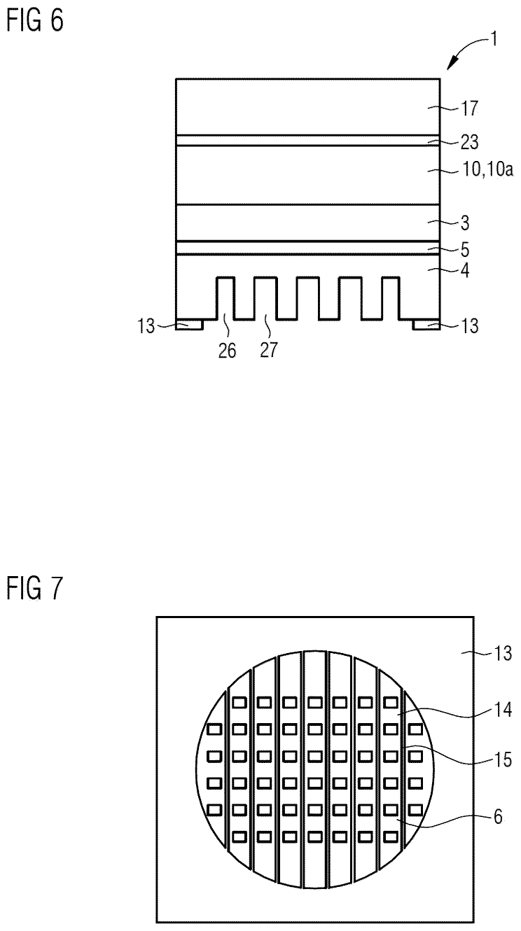

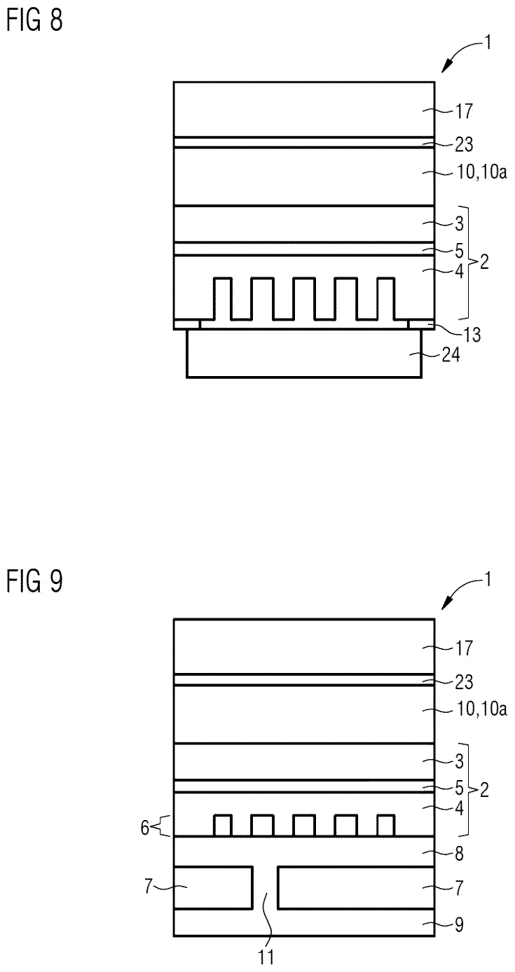

FIGS. 6 and 8 show cross-sections through a semiconductor laser according to exemplary embodiments.

FIG. 7 shows a top view of a semiconductor laser according to an exemplary embodiment.

FIGS. 9 to 13 show cross-sections through semiconductor lasers according to exemplary embodiments in which the optical structure is arranged in the n-doped layer.

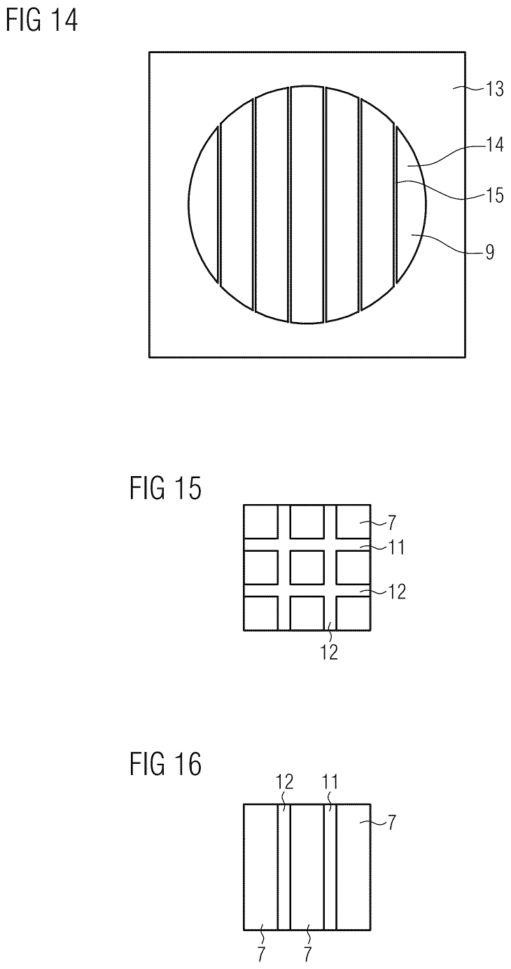

FIG. 14 shows a top view of a semiconductor laser according to an exemplary embodiment.

FIGS. 15 and 16 show sectional views through the high refractive index layer according to exemplary embodiments.

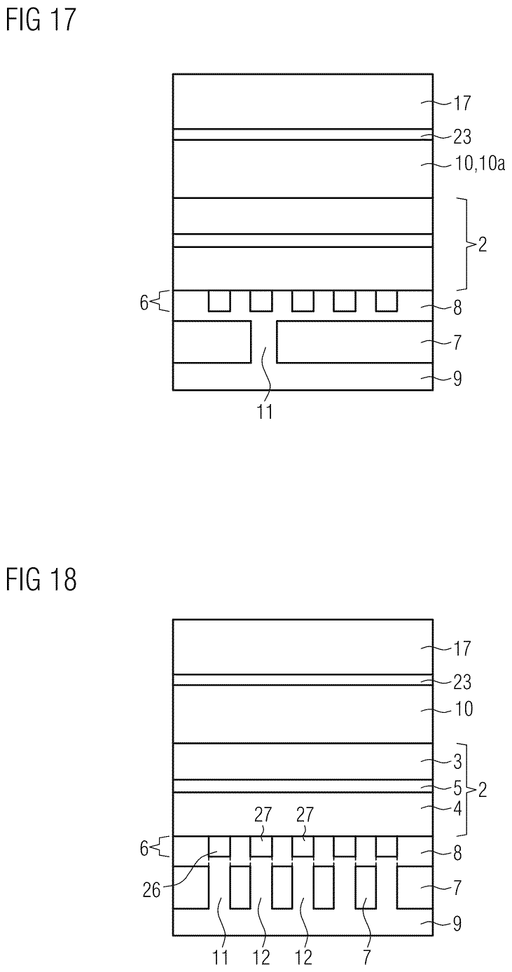

FIGS. 17 and 18 show cross-sections of further exemplary embodiments of a semiconductor laser.

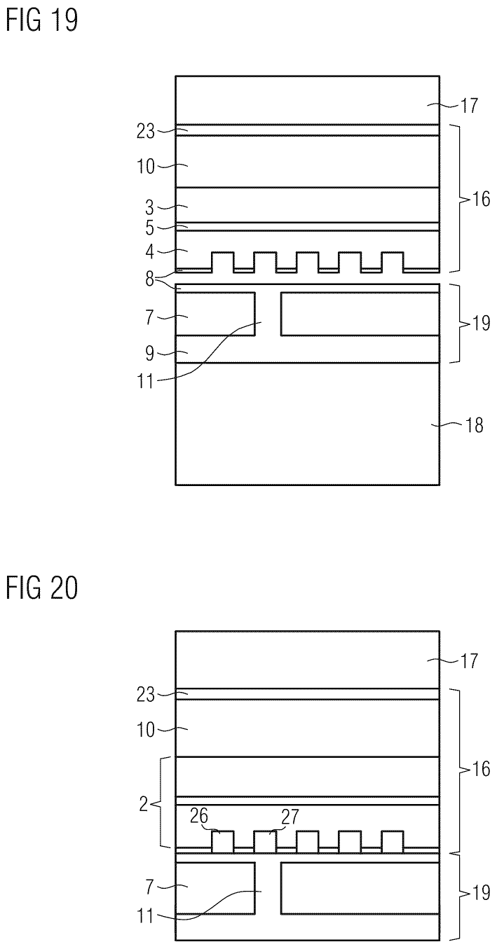

FIGS. 19 and 20 show steps in a method for producing a semiconductor laser according to an exemplary embodiment.

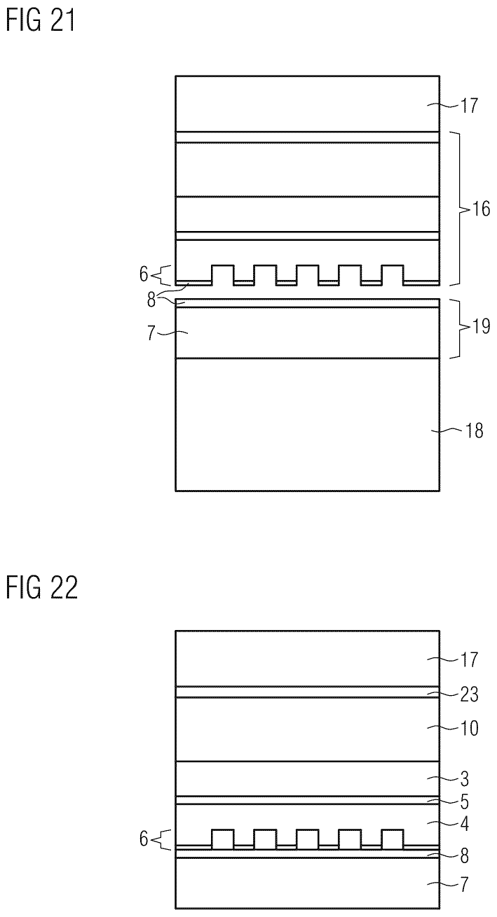

FIGS. 21 and 22 show steps in a method for producing a semiconductor laser according to a further exemplary embodiment.

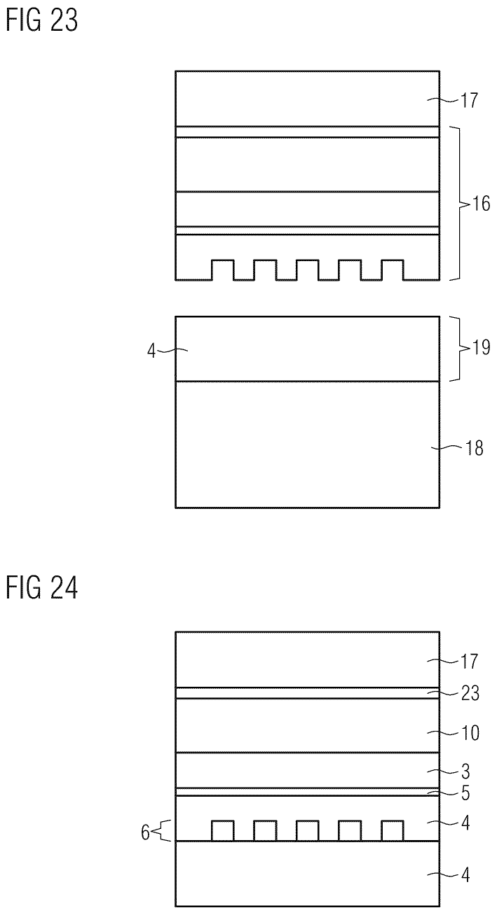

FIGS. 23 and 24 show steps in a method for producing a semiconductor laser according to a further exemplary embodiment.

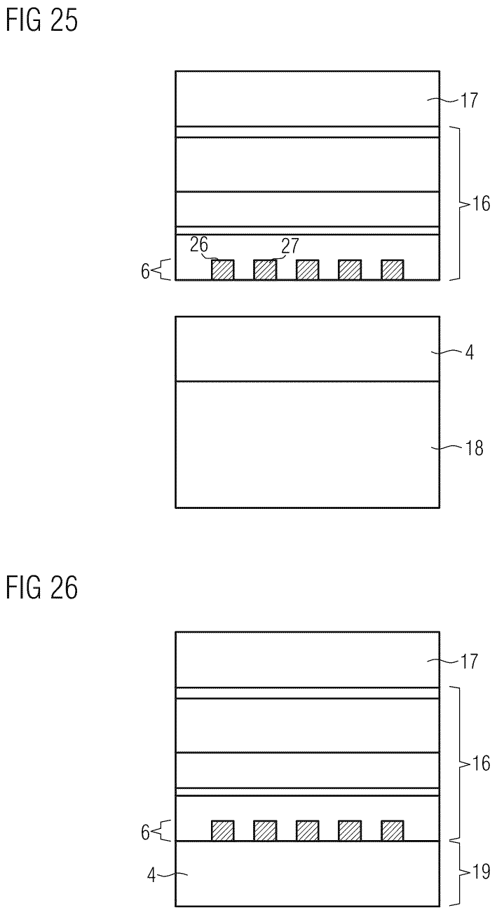

FIGS. 25 and 26 show steps in a method for producing a semiconductor laser according to a further exemplary embodiment.

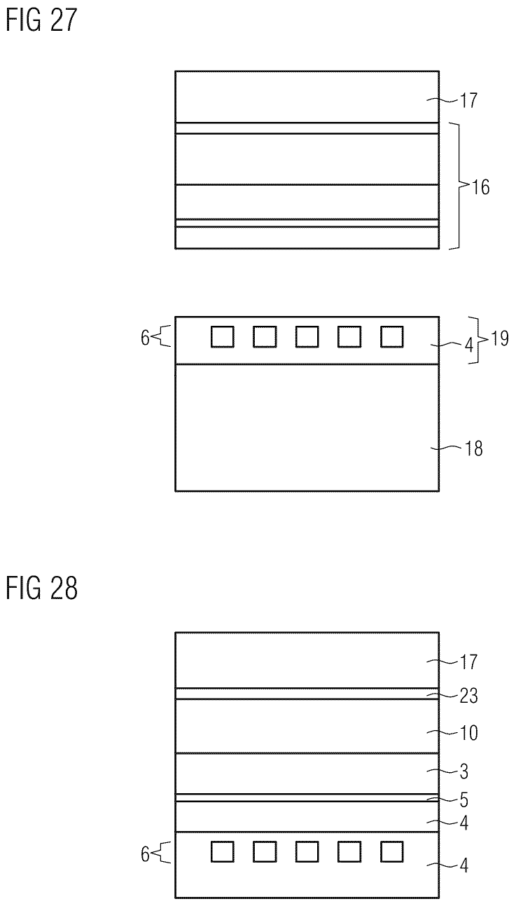

FIGS. 27 and 28 show steps in a method for producing a semiconductor laser according to a further exemplary embodiment.

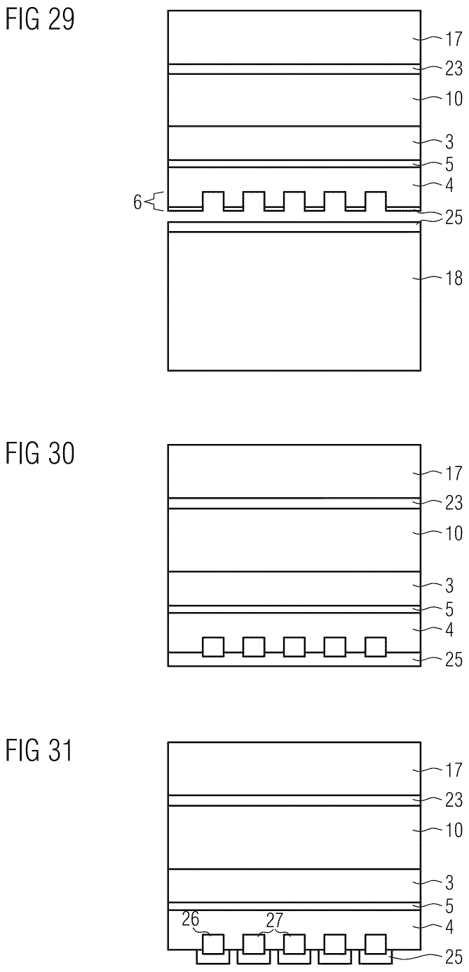

FIGS. 29, 30, 31, 32 and 33 show steps in a method for producing a semiconductor laser according to a further exemplary embodiment.

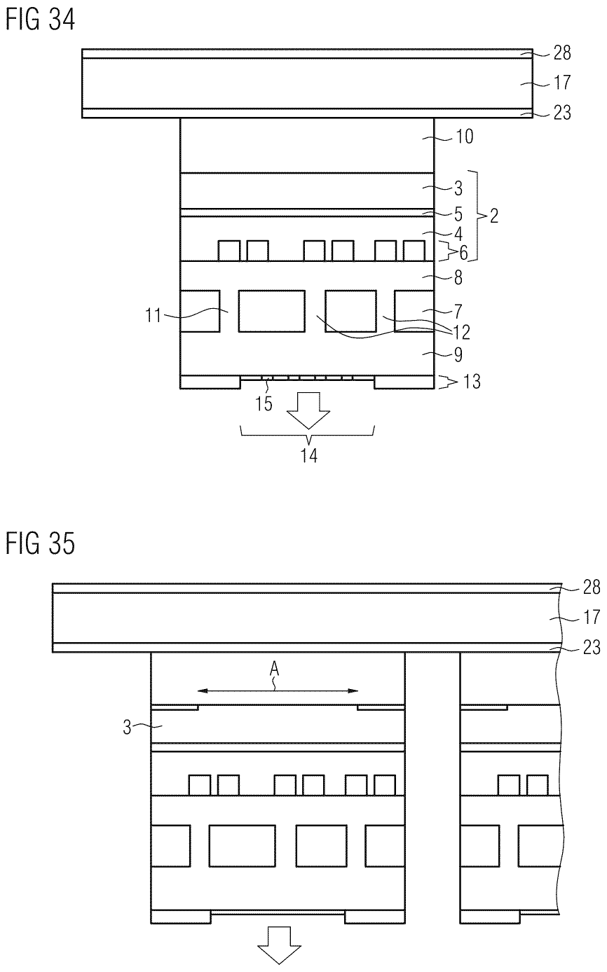

FIGS. 34, 35, 36, 37 and 38 show semiconductor lasers according to further exemplary embodiments.

FIG. 39 shows a top view of a semiconductor laser according to an exemplary embodiment. Here

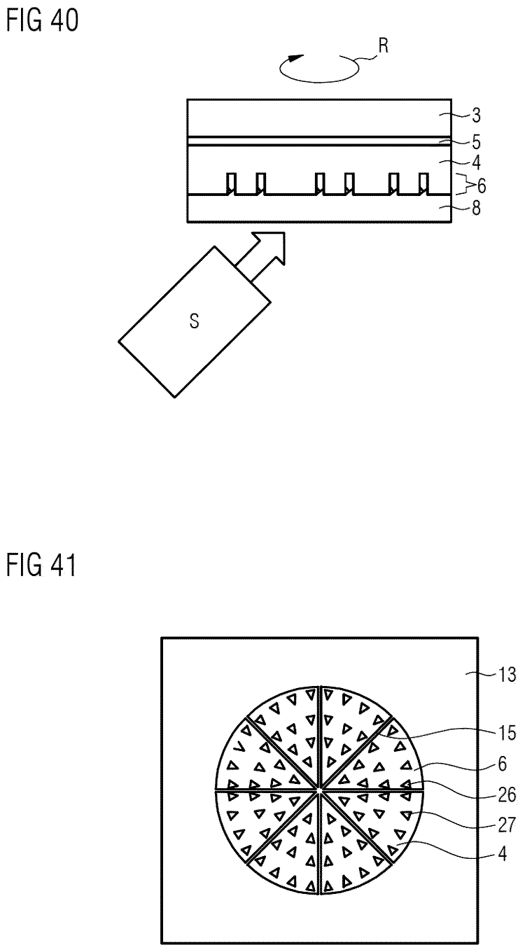

FIG. 40 shows a method step in a method for producing a semiconductor laser according to a further exemplary embodiment.

FIG. 41 shows a top view of a semiconductor laser according to an exemplary embodiment.

Elements that are identical, similar or have the same effect are marked with the same reference signs in the figures. The figures and the proportions of the elements shown in the figures are not to be regarded as true to scale. Rather, individual elements, in particular layer thicknesses, may be shown in exaggerated size for better visualization and/or understanding.

FIG. 1 shows a semiconductor layer sequence 2 grown on a substrate 20 with an n-doped layer 4, a p-doped layer 3 and an active region 5 arranged between the n-doped layer 4 and the p-doped layer 3 according to an exemplary embodiment. The semiconductor layer sequence 2 can at least partially form a semiconductor laser 1. The n-doped layer 4 of the semiconductor layer sequence 2 faces the growth substrate 20. This can mean that the n-doped layer 4 is first grown onto the growth substrate 20. A release layer 21 is arranged between the n-doped layer 4 and the growth substrate 20. Alternatively, the growth substrate 20 can comprise or include a release layer 21. The release layer 21 is then preferably arranged on or at the side of the growth substrate 20 facing the semiconductor layer sequence 2. By means of the release layer 21, the growth substrate 20 can be removed from the semiconductor layer sequence 2, for example.

FIGS. 2 to 5 show the growth substrate 20 shown in FIG. 1 with semiconductor layer sequence 2 grown thereon in further exemplary embodiments, wherein FIGS. 2 to 5 differ from FIG. 1 in that additional layers are arranged on the p-doped layer.

In FIGS. 2, 3 and 4, a low refractive index layer 10 is arranged on the side of the semiconductor layer sequence 2 facing away from the growth substrate 20. The low refractive index layer 10 is applied to the semiconductor layer sequence 2, for example, after the semiconductor layer sequence 2 has been grown on the growth substrate 20. A metal reflector 23 is arranged on the side of the low-refractive index layer 10 facing away from the semiconductor layer sequence 2. The metal reflector 23 can be directly adjacent to the low refractive index layer 10.

In the exemplary embodiment of FIG. 2, the low refractive index layer 10 comprises an ITO layer 10a and a Bragg mirror 10b. The low refractive index layer 10 comprises, for example, a refractive index, for example an average refractive index, which is smaller than a refractive index, for example an average refractive index, of the semiconductor layer sequence 2.

Alternatively, as shown in the exemplary embodiment of FIG. 3, the low refractive index layer 10 can only comprise and/or consist of the ITO layer 10a.

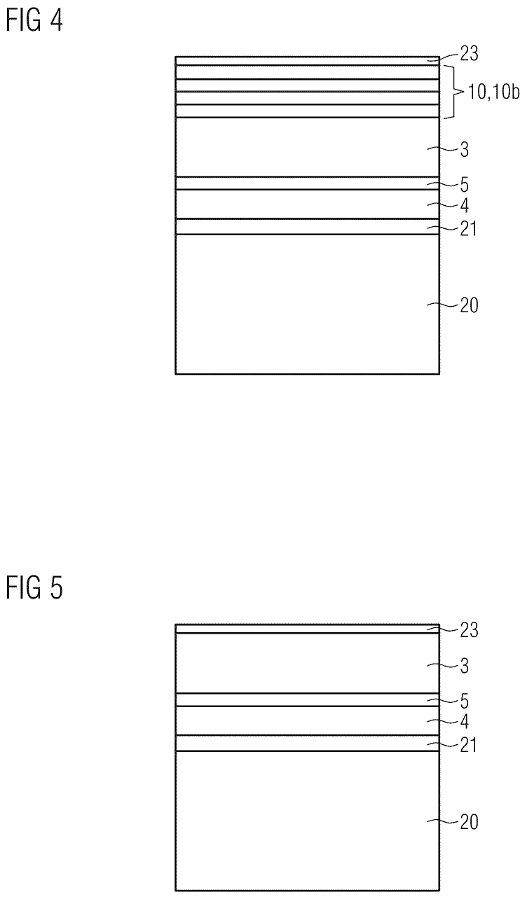

In the exemplary embodiment shown in FIG. 4, the low refractive index layer 10 comprises exclusively a Bragg mirror 10b. Alternatively, not shown, the low refractive index layer 10 can comprise further layers and/or layer stacks.

FIG. 5 shows an exemplary embodiment in which the metal reflector 23 is directly adjacent to the semiconductor layer sequence 2 and in particular directly adjacent to the p-doped layer 3.

FIG. 6 shows a semiconductor laser 1 according to an exemplary embodiment. The structure of the semiconductor laser 1 essentially corresponds to the structure shown in FIG. 3. Deviating from this, the n-doped layer 4 of the semiconductor layer sequence 2, for example, comprises a large layer thickness. For example, the layer thickness of the n-doped layer 4 is at least 300 nm. On the side of the n-doped layer 4 facing away from the active region 5, for example, a contacting 13 shown in FIG. 7 is arranged. The cut-outs or PC holes 26, 27 comprise a large depth, for example. For example, the cut-outs or PC holes 26, 27 comprise a depth in the range from 20 nm up to and including 150 nm. A carrier is arranged on the side of the metal reflector 23 facing away from the semiconductor layer sequence 2.

FIG. 7 shows a top view of a semiconductor laser 1 according to an exemplary embodiment. The semiconductor laser 1 comprises a contacting 13. The contacting 13 can be arranged on the side of the n-doped layer 4 facing away from the active region 5. For example, the contacting 13 is arranged on the optical structure 6. That the contacting 13 is arranged on the n-doped layer 4 and/or on the optical structure 6 can mean that the contacting 13 is at least in places, in particular completely, in direct contact with the n-doped layer 4 and/or the optical structure 6. In particular, the contacting 13 can be electrically conductively connected to the n-doped layer 4 and/or the optical structure 6.

The contacting 13 comprises an opening 14. The opening 14 can be completely surrounded laterally by the material of the contacting 13. In particular, the opening 14 is at least partially free of the material of the contacting 13. At least one conductive connection 15 is arranged in the opening 14. For example, at least two conductive connections 15 or a plurality of conductive connections 15 are arranged in the opening 14. The conductive connections 15 extend, for example, from the contacting 13 into the opening 14. For example, the at least one conductive connection 15 extends completely over the opening 14. The at least one conductive connection 15 can be formed as a wire. In the exemplary embodiment shown here, a plurality of conductive connections 15 extends over the opening 14. The conductive connections 15 are spaced apart from one another. For example, the conductive connections 15 are arranged in pairs spaced apart from one another. The conductive connections 15 run parallel or nearly parallel to each other. Alternatively, not shown, the conductive connections 15 can run obliquely to each other and/or at least partially touch each other directly. Preferably, the at least one conductive connection 15 runs perpendicular to a polarization of the polarized electromagnetic radiation emitted by the active region 5 of the semiconductor laser 1.

FIG. 8 shows a semiconductor laser 1 according to an exemplary embodiment. The semiconductor laser 1 of FIG. 8 differs from the semiconductor laser 1 shown in FIG. 6 in that a cover 24 is arranged on the optical structure 6. The cover 24 is arranged, for example, on the side of the contacting 13 facing away from the optical structure 6. In other words, the cover 24 is at least partially applied to the contacting 13. In particular, the cover 24 covers the opening 14 of the contacting 13 at least partially or, for example, completely. The cover 24 comprises, for example, an AR coating. The cover 24 is, for example, transmissive, in particular transparent, for the electromagnetic radiation generated and/or emitted by the active region 5 and/or by the optical structure 6. For example, the cover 24 comprises glass or is formed from it. For example, the cover 24 is connected to the contacting by means of soldering, gluing and/or metal-to-metal bonding.

FIGS. 9 to 13 show exemplary embodiments of a semiconductor laser 1, in which the optical structure 6 is arranged in the n-doped layer 4 and in which a high refractive index layer 7 is arranged on the side of the n-doped layer 4 facing away from the active region 5.

FIG. 9 shows a semiconductor laser 1, in which an electrically conductive layer 8, a high refractive index layer 7 and a further electrically conductive layer 9 are arranged on the optical structure 6. At least one via 11 extends through the high refractive index layer. The at least one via 11 preferably extends from the further electrically conductive layer 9 to the electrically conductive layer 8. In the exemplary embodiment selected here, the via 11 is not adapted to the optical structure 6, for example.

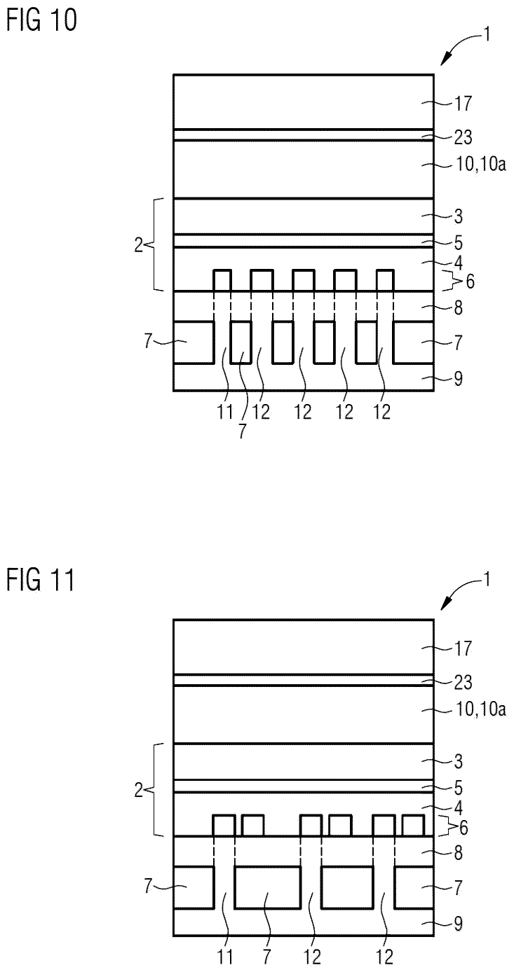

The exemplary embodiment shown in FIG. 10 differs from the exemplary embodiment shown in FIG. 9 in that the high refractive index layer 7 comprises a via 11 and at least one further via 12. The via 11 and/or the at least one further via 12 can be formed as a vertically extending channel, for example channel-shaped. Vertical thereby means in particular that the channel runs perpendicular or almost perpendicular to a main extension plane of the high refractive index layer 7. The via 11 and the at least one further via 12 thereby connect the electrically conductive layer 8 and the further electrically conductive layer 9 in an electrically conducting manner to each other. FIG. 10 shows a schematic mode profile M. Thereby, the mode M overlaps with the optical structure 6. For example, the via 11 and/or the at least one further via 12 overlaps with a PC hole 26,27 in a lateral direction. In particular, the at least one via 11 and/or the at least one further via 12 can completely overlap with a PC hole 26, 27. A lateral expansion of the via 11, 12 can, for example, correspond at least approximately to a lateral expansion of the PC hole 26, 27.

The semiconductor laser 1 of FIG. 11 differs from the exemplary embodiment shown in FIG. 10 in that the via 11 and the at least one further via 12 do not extend each PC cell. For example, the optical structure is formed as a double lattice structure by means of the vias 11, 12.

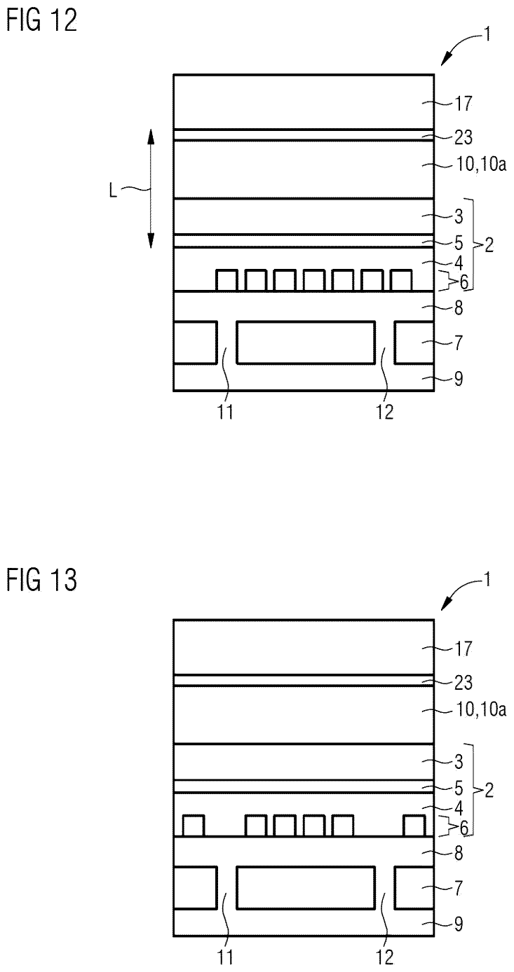

FIGS. 12 and 13 show further exemplary embodiments of a semiconductor laser 1 which differ from the semiconductor laser 1 shown in FIG. 11 in that the distance between the via 11 and the further via 12 is greater. The distance between the vias can be greater than a lattice constant of the optical structure 6. For example, the distance between the vias 11, 12 is a multiple of the distances between areas with different refractive indices in the optical structure 6. A sum of the layer thicknesses L of the p-doped layer 3, the low refractive index layer 10 and/or the metal reflector 23 is, for example, at least 100 nm.

In the exemplary embodiment of FIG. 13, the vias 11, 12 are arranged in such a way that the optical structure 6 comprises no cut-outs or PC holes 26, 27 in the area of the vias 11, 12. A current impression from the electrically conductive layer 8 into the n-doped layer 4 is thus improved.

FIG. 14 shows a top view of a semiconductor laser 1 according to an exemplary embodiment. The semiconductor laser 1 comprises a contacting 13 described in connection with FIG. 7. In the exemplary embodiment of FIG. 14, the contacting 13 is applied onto the further electrically conductive layer 9 of a semiconductor laser 1 shown, for example, in FIGS. 9 to 13.

FIGS. 15 and 16 show sectional views through the high refractive index layer 7 according to exemplary embodiments. In the exemplary embodiment shown in FIG. 15, the vias 11, 12 are formed grid-shaped. In the exemplary embodiment of FIG. 16, the vias 11, 12 are formed line-shaped.

FIGS. 17 and 18 show further exemplary embodiments of a semiconductor laser. The optical structure 6 is formed in the electrically conductive layer 8. This may in particular mean that the optical structure 6 is formed at least partially, in particular partially, by the electrically conductive layer 8 and/or comprises the electrically conductive layer 8. The electrically conductive layer 8 comprises, for example, ITO.

The semiconductor laser 1 of FIG. 18 differs from the semiconductor laser 1 shown in FIG. 17 in that the semiconductor laser 1 comprises at least one further via. In particular, shown here, the number of vias 11, 12 corresponds at least approximately to the number of cells of the optical structure 6. Thereby, the vias 11, 12 comprise a refractive index which is smaller than a refractive index of the high refractive index layer 7. In other words, the optical structure 6 is at least partially extended by the vias 11, 12.

FIGS. 19 and 20 show steps in a method for producing a semiconductor laser 1 according to an exemplary embodiment.

Prior to the method step shown in FIG. 19, for example, a semiconductor layer sequence 2 was grown on a substrate 20. For example, the semiconductor layer sequence 2 was subsequently applied to a carrier and then the substrate 20 was removed. The substrate 20 was removed, for example, with a release layer 21 arranged between the substrate 20 and the semiconductor layer sequence 2. An optical structure 6 was generated in the n-doped layer 4. For example, as shown here, a portion of the electrically conductive layer 8 was applied to the n-doped layer 4 prior to generating the optical structure 6. The optical structure 6 can then, for example, also be generated in the n-doped layer and in the electrically conductive layer 8. For example, prior to the method step shown in FIG. 19, a further electrically conductive layer 9 was grown on a further carrier 18. Subsequently, a high refractive index layer 7 can be applied onto the further electrically conductive layer 9. In particular, at least one via 11 was generated in the high refractive index layer 7 and then at least a portion of the electrically conductive layer 8 was applied onto the high refractive index layer 7. For the at least one via 11, for example, a hole or a channel was formed, which extends through the high refractive index layer 7. The hole or the channel can, for example, be filled with electrically conductive material prior to the application of the electrically conductive layer 8 onto the high refractive index layer 7. Alternatively, the hole or the channel can be filled in the step in which the electrically conductive layer 8 is applied. In the method step of FIG. 19, the carrier 17 with the layer sequence 16 and the further carrier 18 with the further layer sequence 19 are provided.

FIG. 20 shows a finished semiconductor laser 1 according to an exemplary embodiment. Between the method step shown in FIG. 19 and the finished semiconductor laser 1 of FIG. 20, the further layer sequence 19 is connected to the layer sequence 16. In particular, the further layer sequence 19 then adjoins the side of the layer sequence 16 on which the n-doped layer 4 is arranged. Subsequently, the further carrier 18 is removed.

FIGS. 21 and 22 show steps in a method for producing a semiconductor laser 1 according to a further exemplary embodiment. In contrast to the method step shown in FIG. 19, the further layer sequence 19 provided on the further carrier 18 comprises no vias 11, 12. The further layer sequence 19 comprises, as shown here, an electrically conductive layer 8 and a high refractive index layer 7.

FIG. 22 shows a position in the method for producing the semiconductor laser 1 according to an exemplary embodiment. Thereby, the further layer sequence 19 is connected to the layer sequence 16. The further carrier 18 is removed after bonding the layer sequences 16, 19.

Following the state of the method shown in FIG. 22, at least one via 11 is generated. The at least one via 11 is generated, for example, from the side of the further layer sequence 19 facing away from the layer sequence 16. A further electrically conductive layer 9 is applied to the side of the layer sequence 19 facing away from the layer sequence 16, preferably to the high refractive index layer 7.

In the method step shown in FIG. 23 according to an exemplary embodiment, a layer sequence 16 on a carrier 17 and a further layer sequence 19 on a further carrier 18 is provided. The layer sequence 16 differs from the layer sequence 16 shown in FIG. 21 in that the layer sequence 16 does not comprise an electrically conductive layer 8. The n-doped layer 4 thus forms at least partially the outer surface of the layer sequence 16 facing away from the carrier 17. The further layer sequence 19 comprises an n-doped layer 4 and/or is formed from it.

FIG. 24 shows a semiconductor laser 1 produced with the method step shown in FIG. 23. The n-doped layer 4 of the further layer sequence 19 is connected to the n-doped layer 4 of the layer sequence 16.

FIGS. 25 and 26 show steps in a method for producing a semiconductor laser according to a further exemplary embodiment. The method shown here essentially corresponds to the method described in connection with FIGS. 23 and 24. The methods and the semiconductor lasers 1 differ in that the optical structure 6 of FIGS. 25 and 26 is an inverse optical structure 6. This means that a refractive index of the cut-outs 26, 27 in the n-doped layer 4 is higher than a refractive index of the n-doped layer 4.

FIGS. 27 and 28 show steps in a method for producing a semiconductor laser according to a further exemplary embodiment. The exemplary embodiment shown here differs from the exemplary embodiment shown in FIGS. 23 and 24 in that the optical structure 6 is arranged in the further layer sequence 19. The further layer sequence 19 then comprises the n-doped layer 4, for example. The n-doped layer 4 can be arranged on the side of the optical structure 6 facing away from the further carrier 18, as shown here. Alternatively, the optical structure 6 can form an outer surface of the further layer sequence 19 facing away from the further carrier 18. A semiconductor laser 1 shown here is based on GaN, for example. Such a semiconductor laser 1 can, for example, have improved thermal properties. In addition, the active region can be formed defect-free or with particularly few defects.

FIGS. 29, 30, 31, 32 and 33 show steps in a method for producing a semiconductor laser 1 according to a further exemplary embodiment.

In this exemplary embodiment, the further layer sequence 19 is formed from a transparent material 25 with low absorption. The transparent material 25 comprises, for example, SiO₂, NbO and/or SiN. The transparent material 25 also forms, for example, an outer surface of the layer sequence 16 facing away from the carrier 17, FIG. 29.

In FIG. 30, the optical structure 6 is then at least partially confined by the transparent material 25. The further carrier 18 is removed after bonding the further layer sequence 19 to the layer sequence 16.

In the method step shown in FIG. 31, the material 25 is partially removed to expose the n-doped layer 4 in places.

The transparent material 25 is preferably only arranged in the area of the cut-outs 26, 27 of the optical structure 6.

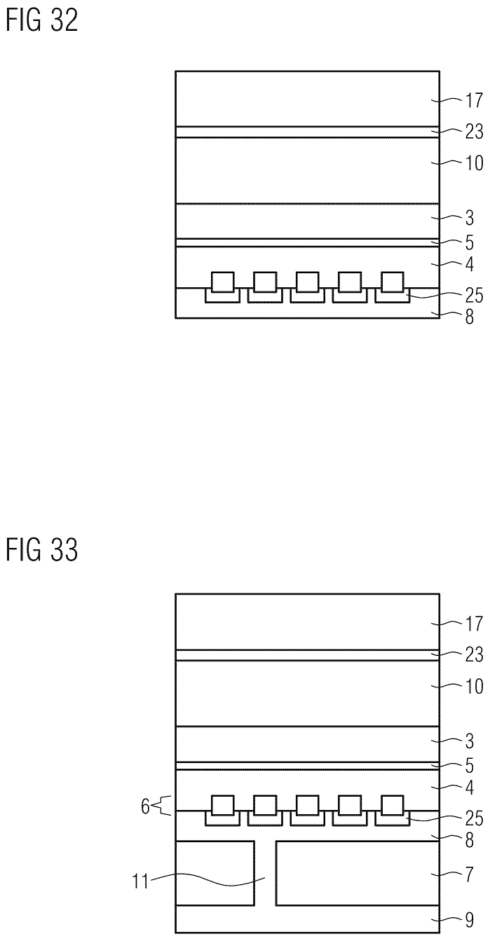

In a subsequent method step, FIG. 32, the electrically conductive layer 8 is applied to the n-doped layer 4 and/or to the transparent material 25.

FIG. 33 shows a finished semiconductor laser 1. After the method step shown in FIG. 32, a high refractive index layer 7, a further electrically conductive layer 9 and vias are arranged on the semiconductor laser 1.

FIGS. 34, 35, 36, 37 and 38 show semiconductor lasers 1 according to further exemplary embodiments.

FIG. 34 shows the semiconductor laser 1 of FIG. 11, wherein a contacting 13 is applied to the further electrically conductive layer 9. The contacting 13 corresponds, for example, to the contacting 13 shown in FIG. 7. An anti-reflection coating 30 is arranged in the opening 14 of the contacting 13. An electrical contact element 28, in particular a p-contact 28, is applied to the side of the carrier 17 facing away from the semiconductor layer sequence 2. For example, the carrier 17 is electrically conductive.

The semiconductor laser 1 of FIG. 35 differs from the semiconductor laser 1 shown in FIG. 34 in that the semiconductor laser 1 comprises a further opening A on the p-doped side. The further opening A is generated, for example, by arranging a dielectric material outside the further opening A or by plasma-assisted etching, for example by reactive ion etching of areas outside the further opening A. For example, the p-doped side comprises a mesa, which is formed, for example, by etching. A lateral extension of the mesa corresponds, for example, at least approximately to a lateral extension of the further opening A.

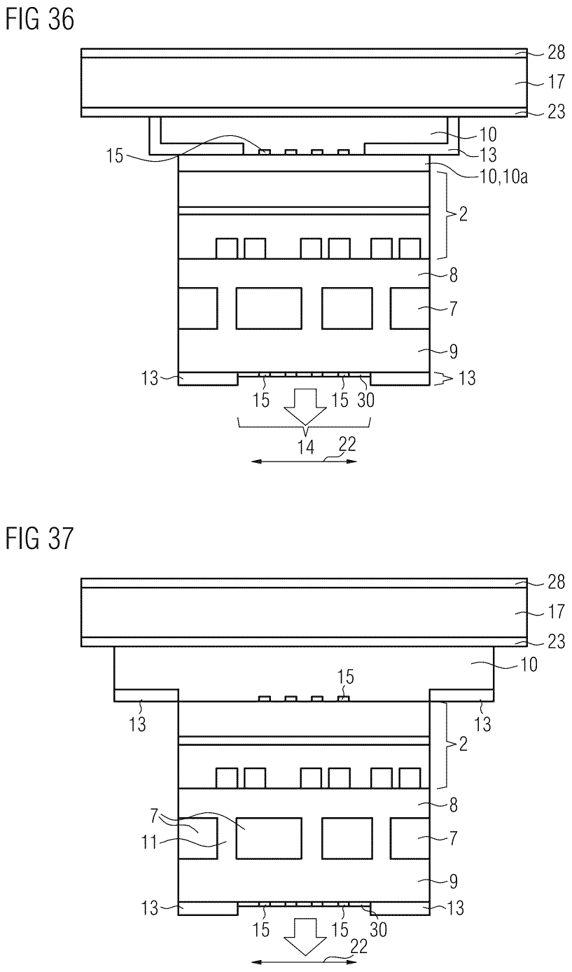

FIG. 36 shows a semiconductor laser 1 which differs from the semiconductor laser 1 shown in FIG. 34 in that a contacting 13 is arranged on the p-doped side. In addition, the low refractive index layer 10 between the carrier 17 and the semiconductor layer sequence 2 is at least partially formed by a low refractive index dielectric, for example SiO₂. This can reduce absorption in the low refractive index layer 10. The contacting 13 is, for example, electrically conductively connected to the metal reflector 23 and/or to the electrical contact element 28. Due to the contacting 13, a better electrical and/or thermal connection can be achieved.

In contrast to the semiconductor laser 1 shown in FIG. 36, the low refractive index layer 10 of the semiconductor laser 1 shown in FIG. 37 is formed exclusively from a low refractive index dielectric.

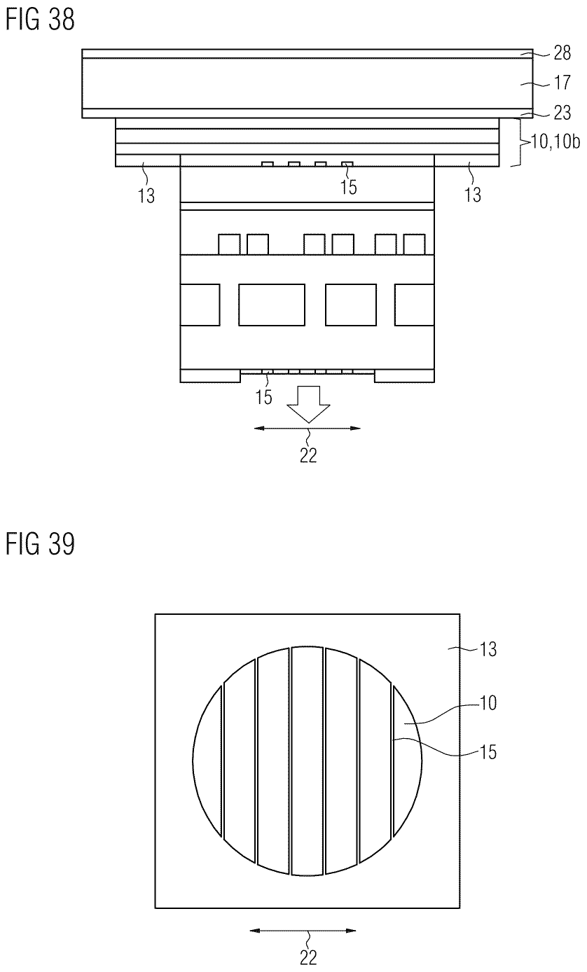

FIG. 38 shows a semiconductor laser 1 that differs from the semiconductor laser 1 shown in FIG. 37 in that the low refractive index layer 10 comprises a Bragg mirror.

FIG. 39 shows a top view of a semiconductor laser 1 according to an exemplary embodiment. For example, it is a top view of the p-doped side 3 of the semiconductor laser 1. The contacting 13 is applied to the low refractive index layer 10. Conductive connections 15 are arranged in the opening 14 of the contacting 13.

FIG. 40 shows a method step in a method for producing a semiconductor laser 1 according to a further exemplary embodiment. Here, the electrically conductive layer 8 is applied to the optical structure 6, for example by oblique sputtering S, or by oblique deposition S using an electron beam. The carrier 17, or the semiconductor layer sequence 2, is rotated R during the application of the electrically conductive layer 8. This allows the electrically conductive layer 8 to extend partially into the cut-outs 26, 27 of the optical structure 6. Subsequently, the electrically conductive layer 8 can be planarized. Preferably, the electrically conductive layer 8 can be applied by means of the method shown in connection with FIG. 40 if the cut-outs comprise a lateral expansion of at most 100 nm, for example at most 50 nm, in particular at most 20 nm, and a depth of at least 50 nm, at least 100 nm or at least 150 nm.

FIG. 41 shows a top view of a semiconductor laser 1 according to an exemplary embodiment. FIG. 41 shows the contacting 13 on the n-doped layer 4. The contacting 13 comprises an opening 14 and conductive connections 15. The conductive connections 15 are in direct contact with each other at least in places in the opening 14. For example, as shown here, the conductive connections 15 run in a star shape, starting from an intersection point. The cut-outs 26, 27 of the optical structure 6 comprise, for example, an approximately triangular base form. The cut-outs 26, 27 are arranged, for example, in a circle around the intersection of the conductive connections 15.

The features and exemplary embodiments described in connection with the figures can be combined with one another in accordance with further exemplary embodiments, even if not all combinations are explicitly described. Furthermore, the exemplary embodiments described in connection with the figures may alternatively or additionally comprise further features according to the description in the general part.

This patent application claims the priority of the German patent application 102022134979.9, the disclosure content of which is hereby incorporated by reference.

The invention is not limited to the description based on the exemplary embodiments. Rather, the invention includes any new feature as well as any combination of features, which includes in particular any combination of features in the patent claims, even if this feature or combination itself is not explicitly stated in the patent claims or exemplary embodiments.

### LIST OF REFERENCE SIGNS

1 semiconductor laser
2 semiconductor layer sequence
3 p-doped layer
4 n-doped layer
5 active region
6 optical structure
7 high refractive index layer
8 electrically conductive layer
9 further electrically conductive layer
10 low refractive index layer
10a ITO layer
10b Bragg mirror (DBR)
11 via
12 further via
13 contacting
14 opening
15 conductive connection
16 layer sequence
17 carrier
18 further carrier
19 further layer sequence
20 growth substrate
21 release layer
22 polarization
23 metal reflector
24 cover
25 transparent material
26 PC hole
27 further PC hole
28 contact element (p-contact)
30 AR coating
M mode profile
L length
A further opening
S oblique sputtering
R rotation

1. A semiconductor laser comprising
a semiconductor layer sequence with a p-doped layer, an n-doped layer and an active region arranged between the p-doped layer and the n-doped layer for generating electromagnetic radiation, and
an optical structure, wherein
the optical structure is arranged on the side of the active region facing away from the p-doped layer,
the optical structure comprises a refractive index varying in a lateral direction for the electromagnetic radiation generated by the active region, and
the n-doped layer is arranged at least partially between the active region and the optical structure, wherein
the optical structure is arranged on the side of the n-doped layer facing away from the active region.

2. The semiconductor laser according to claim 1, wherein the optical structure comprises a photonic crystal.

3. The semiconductor laser according to claim 1, wherein a high refractive index layer is arranged on the side of the n-doped layer facing away from the active region, wherein a refractive index of the high refractive index layer is at least 1.7.

4. The semiconductor laser according to claim 3, wherein the high refractive index layer is transmissive for the electromagnetic radiation generated by the active region.

5. The semiconductor laser according to claim 3, wherein an electrically conductive layer is arranged between the high refractive index layer and the n-doped layer, wherein the electrically conductive layer is configured to contact the n-doped layer electrically.

6. The semiconductor laser according to claim 3, wherein a further electrically conductive layer is arranged on the side of the high refractive index layer facing away from the active region, and the high refractive index layer comprises at least one via.

7. The semiconductor laser according to claim 6, wherein the semiconductor laser comprises at least one further via, and the at least one via and the at least one further via are configured to at least partially extend the optical structure.

8. The semiconductor laser according to claim 3, wherein the high refractive index layer comprises NbO, TiO and/or GaN.

9. The semiconductor laser according to claim 3, wherein the high refractive index layer comprises a thickness of at least 150 nm.

10. The semiconductor laser according to claim 1, wherein a low refractive index layer is arranged on the side of the p-doped layer facing away from the active region, wherein a refractive index of the low refractive index layer is smaller than an average refractive index of the semiconductor layer sequence.

11. The semiconductor laser according to claim 1, wherein
the semiconductor laser comprises a contacting,
the contacting comprises an opening, and
at least one conductive connection is arranged in the opening.

12. The semiconductor laser according to claim 11, wherein the active region emits polarized electromagnetic radiation having a polarization during operation of the semiconductor laser, and the at least one conductive connection runs perpendicular to the polarization of the polarized electromagnetic radiation.

13. The semiconductor laser according to claim 1, wherein the n-doped layer comprises a thickness of at least 300 nm.

14. A method for producing a semiconductor laser, comprising the following steps:
providing a layer sequence comprising a semiconductor layer sequence with a p-doped layer, an n-doped layer and an active region arranged between the p-doped layer and the n-doped layer for generating electromagnetic radiation on a carrier,
providing a further carrier with a further layer sequence arranged on the further carrier,
forming an optical structure, wherein the optical structure comprises a refractive index varying in the lateral direction for the electromagnetic radiation generated by the active region, and
bonding the layer sequence to the further layer sequence, wherein
the n-doped layer is arranged at least partially between the active region and the optical structure, and
the optical structure is arranged on the side of the n-doped layer facing away from the active region.

15. The method for producing a semiconductor laser according to claim 14, wherein the optical structure is formed in the layer sequence or in the further layer sequence prior to bonding the layer sequence to the further layer sequence.

16. The method for producing a semiconductor laser according to claim 14, wherein the optical structure is formed in the layer sequence and is at least partially confined by the further layer sequence after bonding the layer sequence to the further layer sequence.

17. The method for producing a semiconductor laser according to claim 14, wherein after bonding the layer sequence to the further layer sequence, vias are formed in the further layer sequence.

18. The method for producing a semiconductor laser according to claim 14, wherein the further carrier is removed after bonding the layer sequence to the further layer sequence.

19. The method for producing a semiconductor laser according to claim 14, wherein a semiconductor laser according to claim 1 is produced.
